(19) United States
(12) Patent Application Publication
(10) Pub. No.: US 2012/0263939 A1
(43) Pub. Date: Oct. 18, 2012

(54) Graphene Composite Electrode And Method Of Making Thereof

(76) Inventors: Xiaoming Tao, Hong Kong (HK); Zijian Zheng, Hong Kong (HK); Haixin Chang, Sendai (JP)

(21) Appl. No.: 13/088,412

(22) Filed: Apr. 17, 2011

(51) Int. Cl. B32B 5/16

(52) U.S. Cl. 428/323

(57) ABSTRACT

A graphene composite electrode and method fabricating thereof. The electrode comprising a large sized graphene sheets, i.e., with an average size larger than 10 in length. The graphene sheets set is doped into an conducting polymer which is further spun coated onto a suitable substrates to form an electrode. The resulting electrode has sufficiently suitable properties in terms of transparency, flexibility and sheet resistance for being used in a wide variety of optoelectronic devices.

### FIELD OF THE INVENTION

The present invention relates to the field of optoelectronic devices. More specifically, it relates to a novel electrode material, which are both electrically conductive and optically transparent and thus are useful in fabricating optoelectronic devices.

### BACKGROUND OF THE INVENTION

In addition to being electrically conductive and optically transparent, next-generation electrode materials for optoelectronic devices are required to be lightweight, flexible, low-cost, and compatible with large-scale manufacturing. Existing electrode materials used in rigid optoelectronic devices are dominated by tin-doped indium oxide (ITO), which however cannot fulfill the aforementioned requirements. ITO is rigid and brittle and cracks when bent or stretched, leading to a dramatic decrease in its conductivity. Furthermore, the ever-increasing price of indium also creates an urgent need to find alternatives. As a result, much research has been focused on the development of new types of flexible electrode materials to replace ITO in the past decade. The most important results among the advances in new electrode material search are carbon nanotubes (CNTs), metal gratings, and random networks of metallic nanowires. More recently, graphene—a novel carbon nanomaterial consisting of one atom-thick, hexagonally arranged carbon atoms—has attracted extensive attention because of its unique electronic and optical properties, and is also recognized to be a good electrode material for making flexible electronic electrodes because it is highly-conductive, transparent, bendable, air and high-temperature stable. To date, two basic strategies have been explored for making graphene electrodes. The first strategy is based on solution casting of graphene oxide onto a substrate, followed by high temperature annealing to reduce graphene oxide into graphene. The second route is metal (Ni, Cu) catalyzed chemical vapor deposition (CVD) of graphene followed by transfer printing to target substrates. The former method is convenient in terms of coating process. However, the temperature (typically above 1000° C.) is not suitable for most substrate materials used in current technology. For example, glass and polyethylene terephthalate (PET) melt at temperature higher than 500° C. and 250° C., respectively. Although the later method does not need high temperature, it requires very expensive and complicated CVD instrument. Furthermore, the transfer printing process is not easy to handle and scale up. Indeed, highly desirable is a low-cost high-throughput and facile method for making graphene electrode without the need for high temperature annealing, vacuum equipment, or any additional transfer printing process.

### SUMMARY OF THE INVENTION

Accordingly, an object of the present invention is to provide a method/technique to produce stable graphene solutions and graphene/conductive polymer composites. This object is achieved by a novel process that starts with the synthesis of surfactant-modified graphene oxide followed by in-situ reduction with hydrazine to obtain large graphene sheets (up to 50 μm in length) with gram quantity and good solubility in aqueous. Such chemically derived graphene is then doped into a conducting polymer, for example, poly(3,4-ethylenedioxythiophene) poly(styrenesulfonate) (PEDOT:PSS), which can be readily spincoated onto substrates such as glass and PET. A mild annealing of the resulting thin films at 150° C. (to remove residual solvent) yields highly conductive (ca. 80 ohm/square, ca. 105 S/m) graphene composite electrode (GCE). Importantly, the conductivity of the electrode shows high-stability under a test of bending more than 1000 times in air. The transparency is also close to that of ITO (˜80%). OLEDs fabricated with the GCE on PET substrates show 2-fold higher luminescence efficiency compared with the devices made on ITO/PET. It is understood that the aforementioned specific reduction agent (hydrazine), polymer(PEDOT:PSS) and substrates (glass or PET) are disclosed as examples of, rather than limitation to, practicing the present invention. Substitutions and alternatives, recognized by people of ordinary skill in the art, are within the scope of the present invention. This novel method is summarized by the following steps: (1) preparing solution processable graphene solid, (2) preparing graphene composite solution, and (3) treating various substrates with graphene composite solution to obtain graphene composite electrodes.

Stable aqueous graphene solution mentioned above can be achieved by inducing small molecule stabilizers, for example, SDBS as surfactant, and the conductive polymer solutions can be mixed with graphene solution to achieve graphene composite solution. The present invention is useful in making, for example, various electrodes in electronic and optoelectronic devices. For achieving the objective mentioned above, an integrated processing technology is disclosed for preparing graphene composite by:

The various features of novelty which characterize the invention are pointed out with particularity in the claims annexed to and forming a part of this disclosure. For a better understanding of the invention, its operating advantages, and specific objects attained by its use, reference should be made to the drawings and the following description in which there are illustrated and described preferred embodiments of the invention.

### BRIEF DESCRIPTION OF THE DRAWINGS

FIG. 1 is optical images of 1 mg/mL SDBS-graphene aqueous solution (A) and SDBS-graphene powder (B).

FIG. 2. is AFM images (A, C) and corresponding height profiles (B, D) of SDBS-graphene sheets.

FIG. 3 shows the FTIR spectrum of the SDBS-graphene according to the present invention

FIG. 4 are SEM and AFM images of pure PEDOT:PSS (A, C) and SDBS-graphene/PEDOT:PSS (1.6 wt. %) composites (B, D) on PET substrates. Inset: cross sectional SEM image of SDBS-graphene/PEDOT:PSS composites on PET.

FIG. 5 shows (A) a photo of GCE on PET (1.6 wt % SDBS-graphene), (B) sheet resistance testing data, and (C) transparency testing data of GCE/PET with SDBS-graphene of various doping concentrations (0, 0.2, 0.4, 0.8, 1.6 wt. %) and commercially available ITO/PET electrodes.

FIG. 6 shows (A) the scheme of the bending test on GCE/PET, (B) resistance changes of GCE/PET (1.6 wt. %) in the bending test, and (C) resistance changes of ITO/PET in the bending test. R is sheet resistance after the bending test and RO is the initial sheet resistance before the bending test.

FIG. 7 shows current-voltage (A), luminescence-voltage (B), and luminescence efficiency (C) of OLED devices based on ITO/PET and GCE/PET anodes.

FIG. 8 is electroluminescence spectra of OLED devices based on ITO/PET and GCE/PET.

### DETAILED DESCRIPTION OF PARTICULAR EMBODIMENTS OF THE INVENTION

The following describes a particular example of the three steps of the method of the present invention for making a graphene composite electrode for the purpose of illustrating the present invention.

### Preparing Solution Processable Graphene

Graphite powder (325 mesh, Alfa Aesar) was oxidized by the Hummer method to form graphite oxide. The method is known to persons of ordinary skill in the art. Typically, in a specific embodiment, graphite powder (3 g) was added to a solution of concentrated H₂SO₄ (12 mL), with K₂S₂O₈ (2.5 g) and P₂O₅ (2.5 g). The solution was kept at 80° C. for about 5 h followed by cooling to room temperature and diluting with 0.5 L deionized (DI) water. The mixture was filtered and washed to remove residual acid. The product was dried and collected as pre-oxidized graphite. The pre-oxidized graphite was re-oxidized by putting it into 0° C. concentrated H₂SO₄ (120 mL) with gradual addition of KMnO₄ (15 g) under stirring and ice-cooling. The mixture was kept at 35° C. for 2-3 h and diluted gradually at an ice-bath cooled environment with 250 mL de-ionized (DI) water. The mixture was re-diluted with de-ionized water to a total volume of 1 liter and followed by addition 20 mL H₂O₂. The mixture was set for several minutes and accompanied with color changing to brilliant yellow. The mixture was filtered and washed by 1:10 HCl aqueous solution and de-ionized water. The obtained graphite oxide powder was dried and dialyzed for one week in 0.5% graphite oxide dispersion. Different from usual route to exfoliate graphite oxide directly, a step of adding surfactant SDBS was performed before exfoliating graphite oxide by ultrasonication. The presence of SDBS facilitated the exfoliation of graphite oxide and larger size of graphene oxide can be obtained in ultrasonication process. Other surfactants may also be satisfactorily used to replace SDBS, for example, sodium dodecyl sulfate (SDS), alkyl benzene sulfonates, sulfonate fluorosurfactants, alkyl sulfates, alkyl ether sulfates, or an ionic liquid. In this particular embodiment, the graphite oxide was exfoliated by sonicating 0.1 mg/mL graphite oxide solution for over 1 h in the presence of SDBS. The obtained homogenous yellow solution was referred to as the SDBS-graphene oxide solution. The SDBS-graphene oxide was reduced with hydrazine at 100° C. for over 24 h. Black precipitates were filtered and washed with DI water. The resulting powder was dried at 70° C. and collected as black SDBS-graphene for future use. The black SDBS-graphene powder was dissolved in water by mild ultrasonication for several minutes to yield highly stable SDBS-graphene aqueous suspension, which are stable over one month without obvious sediment.

### Preparing Graphene Composite Solution

In this particular embodiment, dimethyl sulfoxide (DMSO) was added to pure PEDOT:PSS aqueous solution (Baytron PH 500) with a ratio of DMSO to PEDOT:PSS 5% (wt. %), and then SDBS-graphene suspension was added to the above solution with a weight ratio of SDBS-graphene to PEDOT:PSS up to 10%. The mixture was ultrasonicated for 5 min to obtain a homogenous solution, which is referred to as graphene composite solution. It is understood that other conducting polymers, such as for example, PEDOT, polyaniline, polypyrole, conjugated polyelectrolytes, may be used to replace PEDOT:PSS to practice the present invention. In principle, all conducting polymers that can be dissolved in the same solution with as-made graphene may be satisfactorily used.

### Making Graphene Composite Electrode

In this particular embodiment, 25 μL graphene composite solution, i.e., the SDBS-graphene/PEDOT:PSS composite solution prepared in the above step, was spun with 250 rpm/min for 15 min on ca. 125 mm2 pre-cleaned 175 μm thick PET substrates (DuPont Teijin Films/Melinex ST504), which was then undergone a process of slow room-temperature drying overnight and additional baking at 150° C. for 15 min to remove the remained solvent to result in a graphene composite electrode. The PET substrate is provided here as an example of, not a limitation to, the present invention. Other substrates, for example, PE, PVC, PP, PS, or glass may be satisfactorily used.

Of course, the specific conditions and parameters used in the above described particular embodiment may be modified by a person of ordinary skill in the art to achieve a satisfactory result without needing undue experimentation.

### Characterizations of SDBS-Graphene

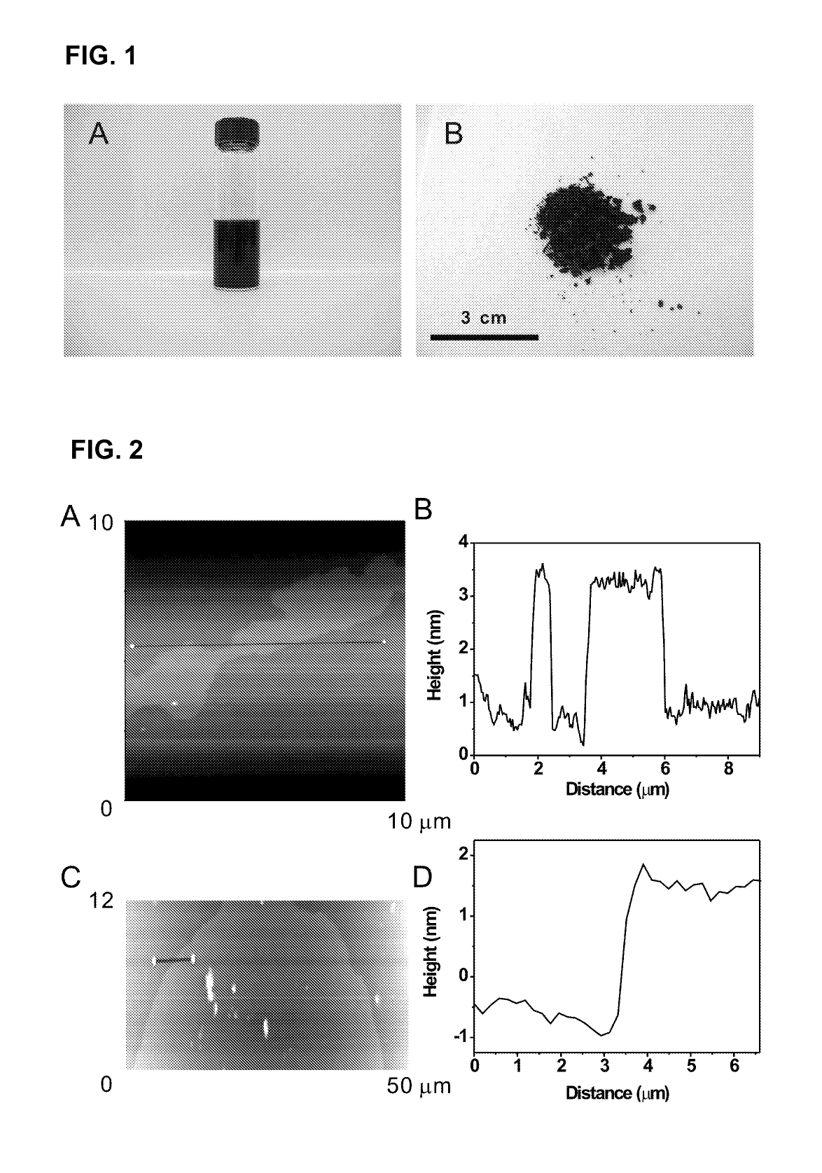

The morphology of the SDBS-graphene prepared above was characterized by digital images and Atomic Force Microscopy (AFM). Photographs of the solution of processable graphene and the product powder are shown in FIGS. 1(A) and (B), respectively. It was confirmed that it was high yield, highly conductive nano-scaled graphene plate nanocomposites, and formed highly stable aqueous suspensions stable over 1 month without obvious sediment. FIG. 2 demonstrates that the graphene has a diameter of over 10 μm and can be as large as 50 μm.

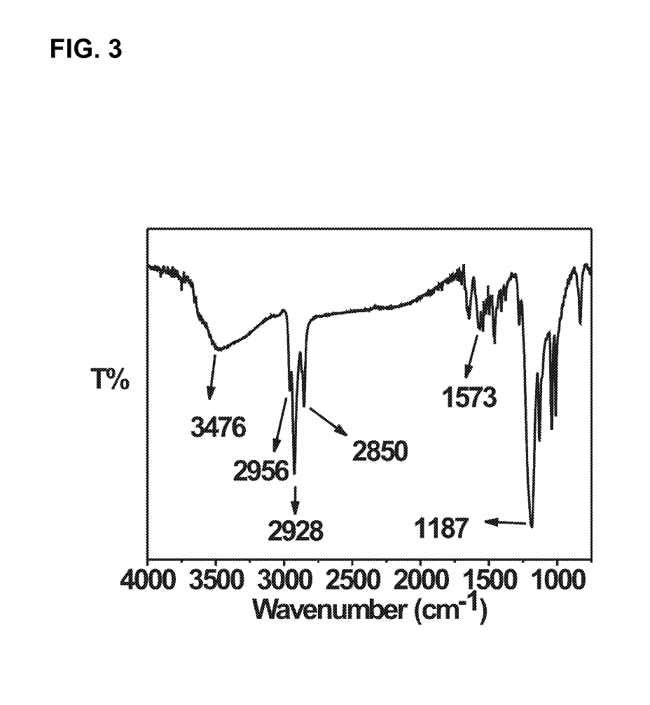

Furthermore, a Fourier Transform Infrared Spectroscope (FTIR) was used to demonstrate the existence of the SDBS on graphene surface. As shown in FIG. 3, the peaks at 2850 cm⁻¹, 2928 cm⁻¹ and 2956 cm⁻¹ are induced by C—H vibrations in SDBS. The peak at ca. 1573 cm⁻¹ is from the vibration of the benzene group. The peaks at 3476 cm⁻¹ and 1187 cm⁻¹ are attributed to the remained —OH groups and C—O—C bonds, respectively, on the graphene surface, which is typical in chemically reduced graphene.

### Characterization of Graphene Composite Electrodes

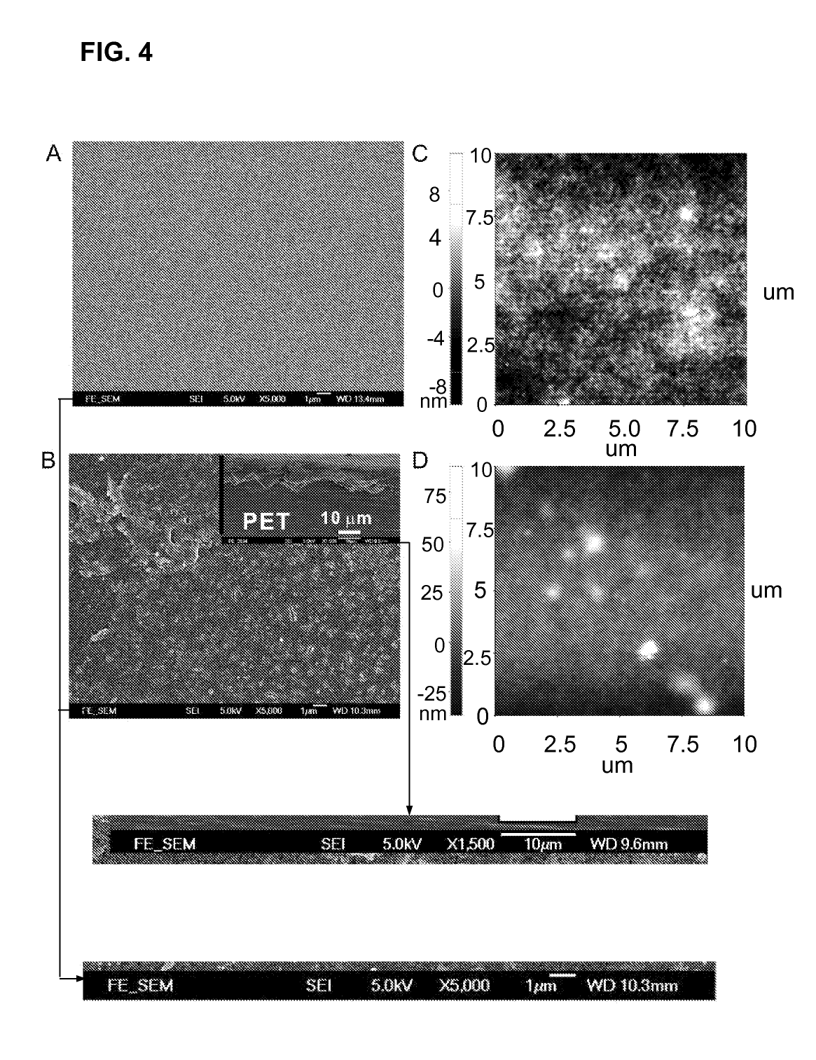

A scanning electron microscopy (SEM) study showed that the surface of the graphene composite electrodes (GCE) made in the above described embodiment is rougher than that of pure PEDOT:PSS films (shown in FIGS. 4A and 4B, respectively, which is typical for the polymer thin films doped with graphene. The cross-section of the GCE show that the SDBS-graphene sheets form a lamella structure with PEDOT:PSS in the thin films (inset of FIG. 4B). AFM roughness evaluations, as shown in FIGS. 4C and 4D, further confirmed that the average roughness (Ra) of pure PEDOT:PSS films was 1.7 nm while Ra of the GCE was 9.2 nm. The thickness of the GCE composite thin film was ca. 150 nm as determined by SEM and AFM (not shown).

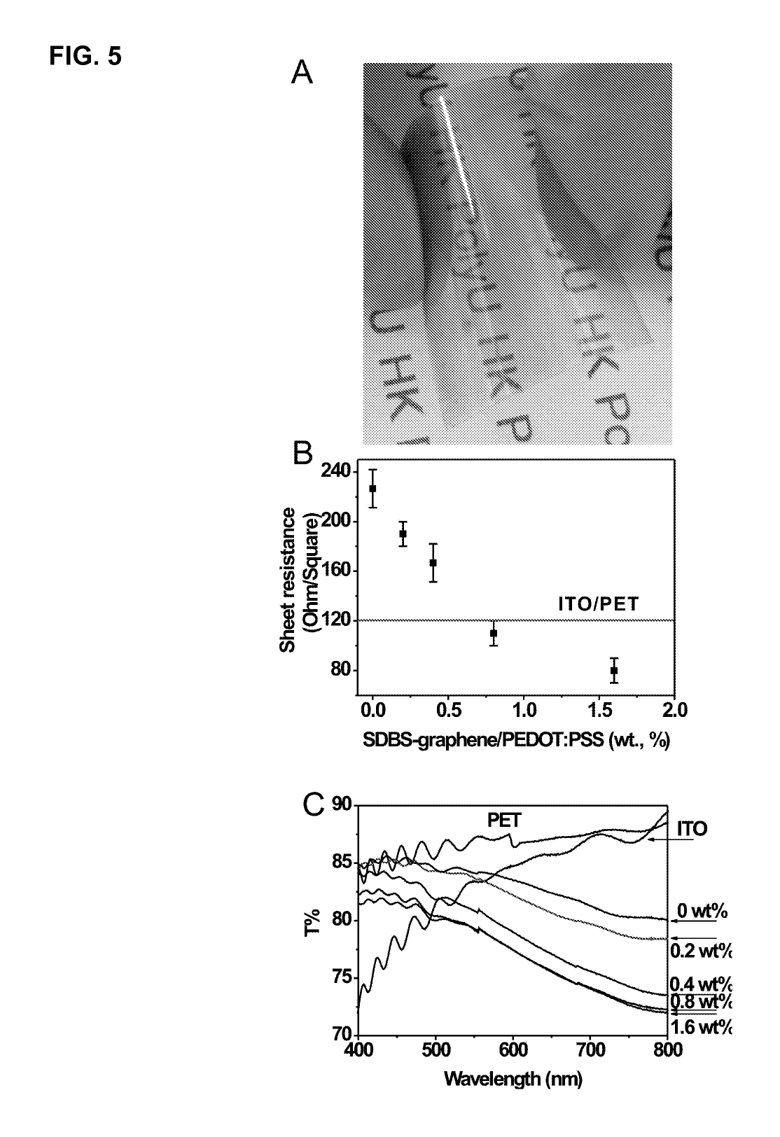

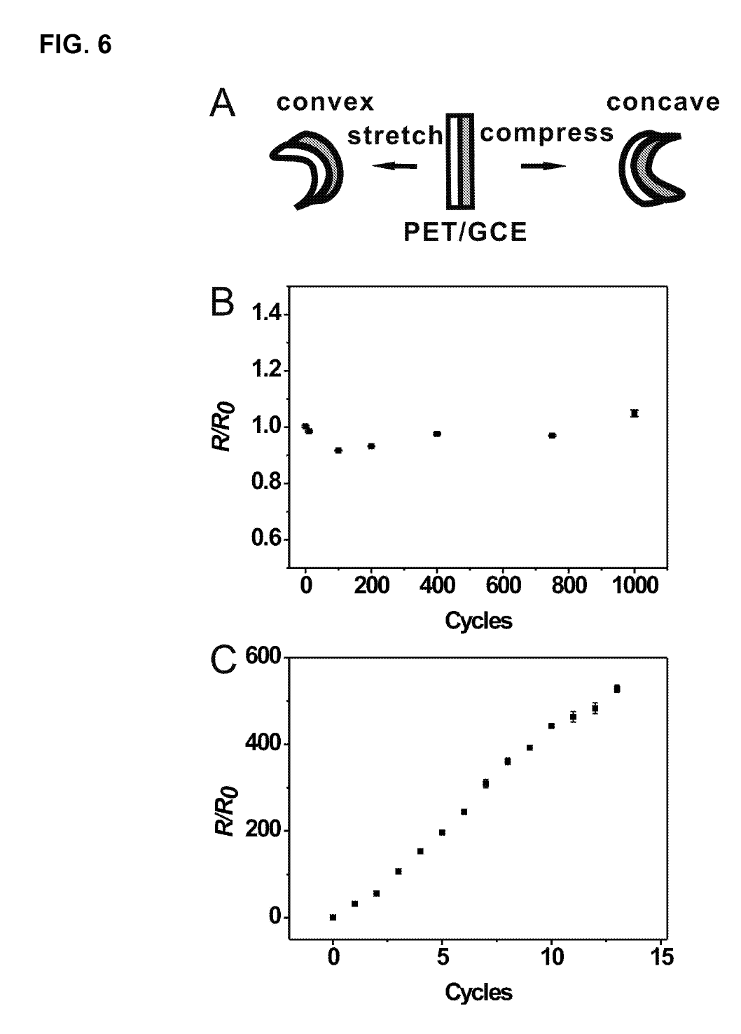

The transparency, sheet resistance, and flexibility of the graphene composite electrode prepared above was then examined. A photo of the graphene composite electrode is shown in FIG. 5A, which was on a 150 mm thick PET substrate. As shown in FIG. 5B, the sheet resistance of the GCE decreased from 227±15 Ω/square to 80±10 Ω/square with increasing weight ratio of SDBS-graphene to PEDOT:PSS from 0% to 1.6%, which equals to a 3-fold increase in conductivity from 3×104 to 1×105 S/m. The decrease in sheet resistance and increase in conductivity can be attributed to the enhancement of electrical network in the polymer matrix by the doping of electrically conductive graphene. Importantly, GCE has high transparency to visible light. The transparency of different electrode materials on PET substrates was measured and the results are shown in FIG. 5C. The transparency at 550 nm decreases slightly from 87% for pure PET substrate to 84% and 79% for PEDOT:PSS/PET and 1.6% GCE/PET, respectively. In other words, the transparency of 1.6% GCE/PET of the present invention and that of commercially available ITO/PET differ only by about 5%. The bending tests were conducted on the GCE/PET with in-situ resistance measurement. The GCE film was bent to a given curvature in two opposite directions for a number of cycles as shown in FIG. 6A. Before bending, the GCE/PET sample was placed perpendicularly to the horizon. One bending cycle includes one stretching and one compression of the GCE. The sample was firstly bent to the convex form, in which the GCE was stretched. It was then bent to the concave structure, in which the GCE was compressed. After 1000 bending cycles, only about 5% increase in the resistance of GCE/PET was observed (FIG. 6B) in contrast with ITO (FIG. 6C), indicating that the GCE of the present invention is highly flexible and resistant to bending fatigue.

### Exemplary Organic Light-Emitting Diode Based on Graphene Composite Electrodes

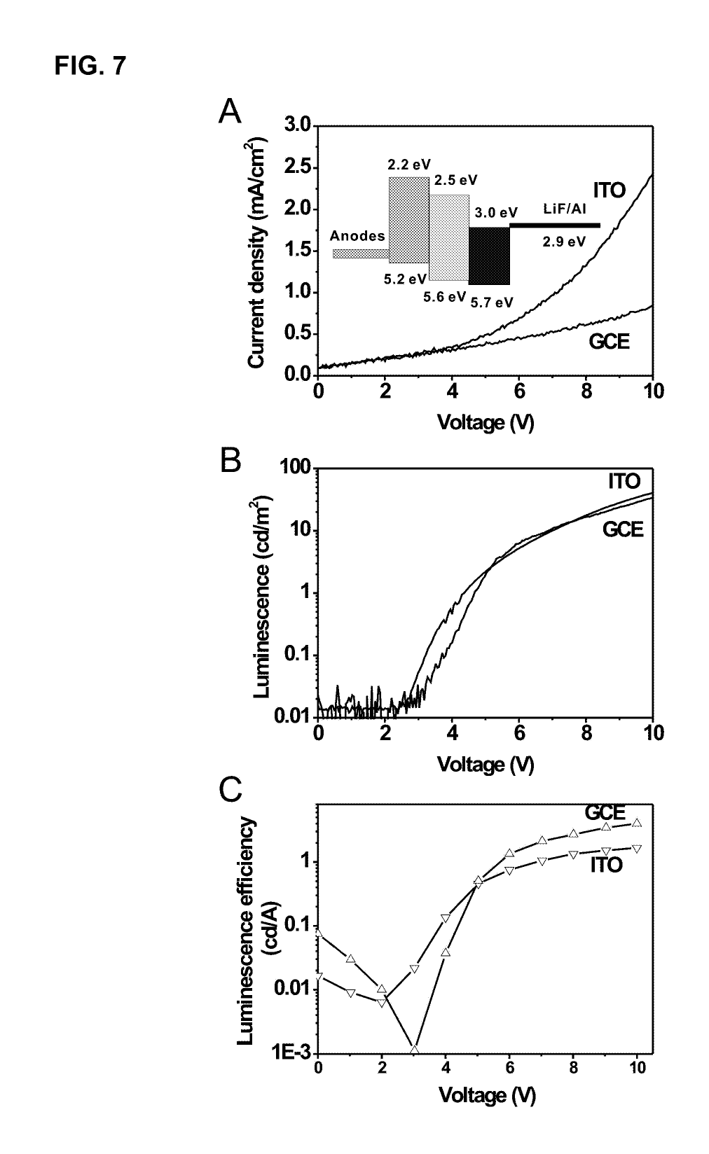

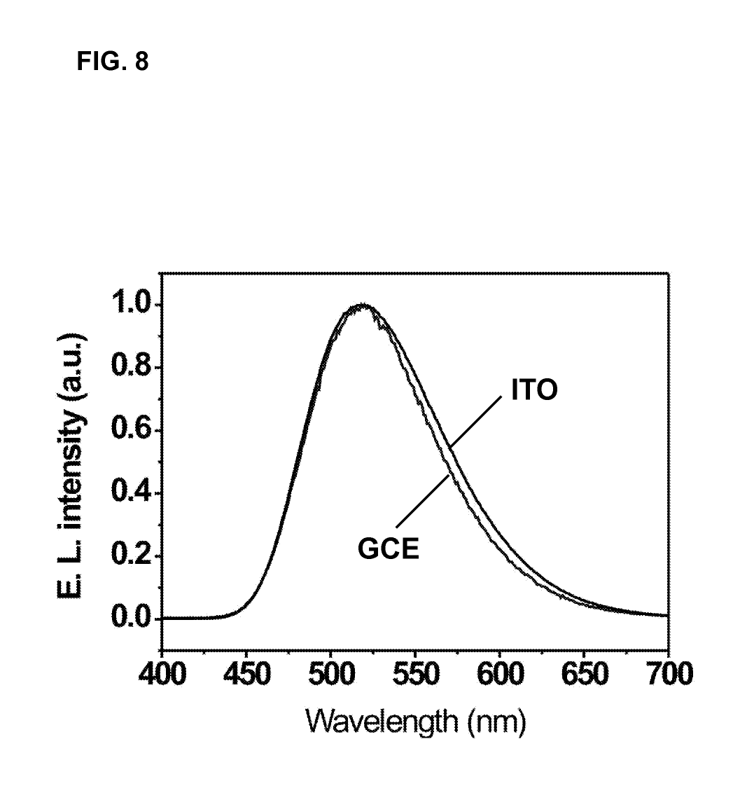

The as-made GCE of the present invention showed a great potential for electrodes of flexible optoelectronic applications. As a prototype, An OLED device based on GCE/PET anode of the present invention was fabricated. FIGS. 7A and 7B represent the current-voltage and luminescence-voltage characteristics of OLED devices based on GCE and ITO anodes, respectively. Both devices exhibit sharp turn-on. The turn-on voltage is 3.1 V and 2.8 V for GCE/PET OLEDs and ITO/PET OLEDs, respectively. At 10 V, the luminescence of GCE/PET OLEDs is 33 cd/m2, slightly less than that of ITO/PET OLEDs (40 cd/m2). This is because the current density of GCE/PET OLEDs is much lower at high voltage, being 0.85 mA/cm2, compared with 2.4 mA/cm2 for ITO/PET OLEDs. The lower current of GCE OLEDs may be induced by increased hole injection capability and more balanced electron-hole recombination. The work functions of PEDOT:PSS and graphene are reportedly about 5.2 eV and 4.5-4.7 eV, respectively. It is therefore believed that the work function of GCE may reach about 5 eV, comparable with that of ITO which is bout 4.7 eV as reported by others. The luminescence efficiency of GCE/PET OLEDs was about 3.9 cd/A at 10 V, about 2 folds higher than that of ITO/PET OLEDs (1.7 cd/A, See FIG. 7C). This efficiency is comparable with the reported efficiency of the OLEDs based on CNT anodes with 2.3 cd/A at ca. 10-15 V or 4.9-8.2 cd/A at 11-16V. The normalization of electroluminescence (EL) spectra (shown in FIG. 8) was conducted by considering the highest EL intensity as 1.0. It shows that the EL of GCE/PET OLEDs has an emission wavelength center at 519 nm, which is a typical value in Alq3 based OLED devices. The center position of the EL spectra of GCE/PET OLEDs was shown to be the same as that of ITO/PET OLEDs.

While there have been described and pointed out fundamental novel features of the invention as applied to a preferred embodiment thereof, it will be understood that various omissions and substitutions and changes, in the form and details of the embodiments illustrated, may be made by those skilled in the art without departing from the spirit of the invention. The invention is not limited by the embodiments described above which are presented as examples only but can be modified in various ways within the scope of protection defined by the appended patent claims.

What is claimed is:

1. A graphene composite electrode, comprising
(a) a plurality of graphene sheets of an average size larger than about 10 μm in length;
(b) a conducting polymer; and
(c) a substrate;
wherein said graphene sheets are doped into said conducting polymer and said conducting polymer is coated onto said substrate.

2. The graphene composite electrode of claim 1, wherein said graphene sheets are of an average size from about 10 μm to about 50 μm.

3. The graphene composite electrode of claim 2, wherein said graphene sheet comprising a surfactant.

4. The graphene composite electrode of claim 3, wherein said surfactant is SDBS.

5. The graphene composite electrode of claim 3, wherein said conducting polymer is PEDOT:PSS.

6. The graphene composite electrode of claim 3, wherein said substrates polymer is glass or PET.

7. A method of fabricating a graphene composite electrode, comprising the steps of:
(a) preparing a plurality of graphene oxide sheets by a process comprising exfoliation facilitated by a surfactant;
(b) preparing a graphene composite suspension by suspending said graphene oxide from step(a) in a polymer; and
(c) coating said graphene composite suspension from step (b) onto a substrate to form an electrode.

8. The method of claim 7, wherein said surfactant of step (a) is SDBS.

9. The method of claim 8, wherein said polymer in step (b) is PEDOT:PSS.

10. The method of claim 9, wherein said substrate in step (c) is glass.

11. The method of claim 9, wherein said substrate in step (c) is PET.

12. The graphene composite electrode of claim 3, wherein said surfactant is sodium dodecyl sulfate, alkyl benzene sulfonates, sulfonate fluorosurfactants, alkyl sulfates, alkyl ether sulfates, or an ionic liquid.

13. The graphene composite electrode of claim 3, wherein said polymer is PEDOT, polyaniline, polypyrole, or conjugated polyelectrolytes.

14. The graphene composite electrode of claim 3, wherein said substrates polymer is PE, PVC, PP, or PS.

15. The method of claim 7, wherein said surfactant of step (a) is sodium dodecyl sulfate, alkyl benzene sulfonates, sulfonate fluorosurfactants, alkyl sulfates, alkyl ether sulfates, or an ionic liquid.

16. The method of claim 8, wherein said polymer in step (b) is PEDOT, polyaniline, polypyrole, or conjugated polyelectrolytes.

17. The method of claim 9, wherein said substrate in step (c) is PE, PVC, PP, or PS.
